(19) United States
(12) Patent Application Publication
(10) Pub. No.: US 2011/0296259 A1
(43) Pub. Date: Dec. 1, 2011

(54) TESTING MEMORY ARRAYS AND LOGIC WITH ABIST CIRCUITRY

(75) Inventors: Bargav Balakrishnan, Poughkeepsie, NY (US); Pradip Patel, Poughkeepsie, NY (US); Antonio R. Pelella, Highland Falls, NY (US); Daniel Rodko, Poughkeepsie, NY (US)

(73) Assignee: INTERNATIONAL BUSINESS MACHINES CORPORATION, Armonk, NY (US)

(21) Appl. No.: 12/787,919

(22) Filed: May 26, 2010

(51) Int. Cl. G11C 29/12; G06F 11/27

(52) U.S. Cl. 714/718; 714/E11.169

(57) ABSTRACT

A method of testing an integrated circuit device, the integrated circuit device having a memory array portion and a logic portion, includes providing test data to the memory array portion of the integrated circuit device using Array Built-In Self Test (ABIST) circuitry; and simultaneously testing the logic portion of the integrated circuit device using the ABIST circuitry, wherein both the memory array portion and the logic portion of the integrated circuit are tested at speed.

### BACKGROUND

The present invention relates generally to integrated circuit memory devices and, more particularly, to a method and structure for simultaneously testing both memory arrays and associated logic using Array Built-In Self Test (ABIST) circuitry.

During the manufacture of semiconductors on wafers, an important aspect of the manufacturing process is to test the circuitry to determine if the configuration is correct. In order to determine if the circuitry is correct, certain test circuitry is employed. The test circuitry determines if there were any errors or anomalies during manufacturing.

Typically, test patterns are input into the circuits on the wafers. If the configuration is correct, then specific output patterns will be produced. Otherwise, the output patterns will be inconsistent with predetermined output patterns to indicate errors. The output patterns can also be used to extrapolate potential problems for future usage or continual problems in the manufacturing process.

Testing the on-chip circuitry, however, requires testing of multiple aspects of the circuitry. For example, testing of array macros can be performed by Array Built-In Self Test (ABIST) circuitry. ABIST circuitry is additional on-chip circuitry that is coupled to an ABIST test engine that allows for screening of mature technology. Additionally, the ABIST test engines have contingency protocols for early hardware screening and failure analysis.

Test engines, such as the ABIST test engines, however, do not typically provide a full complement of analyses for all of the circuitry associated with the integrated circuit memory device. As a result, logic contained with an array macro may not be fully tested by on-chip test circuitry and the associated test engines. To compensate for the lack of analysis for logic within the array macro, Logic Built-In Self Tests (LBISTs) are also employed to increase coverage of the logic within the array macro. Typically, LBIST results are captured into scannable latches to verify correct behavior.

A traditional method for testing Static Random Access Memories (SRAMs) with logic is to test the SRAM cells with ABIST and use LBIST to test the remaining logic (e.g., hit logic, multiplexers, etc.) downstream from the array. However, during LBIST, the SRAM portion of the macro is in “write-through” mode. As a result, read patterns are not included in the LBIST, thus limiting test coverage.

### SUMMARY

In an exemplary embodiment, a method of testing an integrated circuit device, the integrated circuit device having a memory array portion and a logic portion, includes providing test data to the memory array portion of the integrated circuit device using Array Built-In Self Test (ABIST) circuitry; and simultaneously testing the logic portion of the integrated circuit device using the ABIST circuitry, wherein both the memory array portion and the logic portion of the integrated circuit device are tested at speed.

In another embodiment, a method of testing a static random access memory (SRAM) macro having an SRAM array portion and a logic portion includes providing test data to the SRAM array portion of the SRAM macro using Array Built-In Self Test (ABIST) circuitry; and simultaneously testing the logic portion of the SRAM macro using the ABIST circuitry, wherein both the SRAM array portion and the logic portion of the SRAM macro are tested at speed.

In another embodiment, an integrated circuit device includes a memory array portion and a logic portion; an Array Built-In Self Test (ABIST) engine configured to provide ABIST data to the memory array portion; and a Logic Built-In Self Test (LBIST) engine configured to provide LBIST data to the logic portion; wherein the ABIST engine is further configured to selectively provide ABIST data to the logic portion so as to simultaneously test the memory array and logic portions of the integrated circuit device at speed.

In still another embodiment, a static random access memory (SRAM) macro device includes an SRAM array portion and a logic portion; an Array Built-In Self Test (ABIST) engine configured to provide ABIST data to the SRAM array portion; and a Logic Built-In Self Test (LBIST) engine configured to provide LBIST data to the logic portion; wherein the ABIST engine is further configured to selectively provide ABIST data to the logic portion so as to simultaneously test the SRAM array and logic portions of the SRAM macro device at speed.

### BRIEF DESCRIPTION OF THE SEVERAL VIEWS OF THE DRAWINGS

Referring to the exemplary drawings wherein like elements are numbered alike in the several Figures:

FIG. 1 is a schematic block diagram of an existing ABIST/LBIST testing approach;

FIG. 2 is a schematic block diagram of a simultaneous memory and logic testing scheme using ABIST, in accordance with an embodiment of the invention; and

FIG. 3 is a schematic block diagram of an SRAM macro configured for simultaneous memory and logic testing using ABIST, in accordance with a further embodiment of the invention.

### DETAILED DESCRIPTION

Disclosed herein is a method and structure for simultaneously testing, at speed, both memory arrays (e.g., SRAM) and associated logic using ABIST circuitry. In brief, the simultaneous testing is implemented using a single pass/fail compare latch, as well as an ABIST multiplexer (MUX) to uniquely test each memory cell (with another compare latch) to isolate the fail to the SRAM or to the downstream logic. In so doing, both the SRAM and hit logic are tested together, thereby delivering greater test coverage than a traditional random LBIST method. The embodiments herein will provide, for example, a wide variety of multi-cycle read and write patterns versus traditional single-cycle, write-through LBIST patterns.

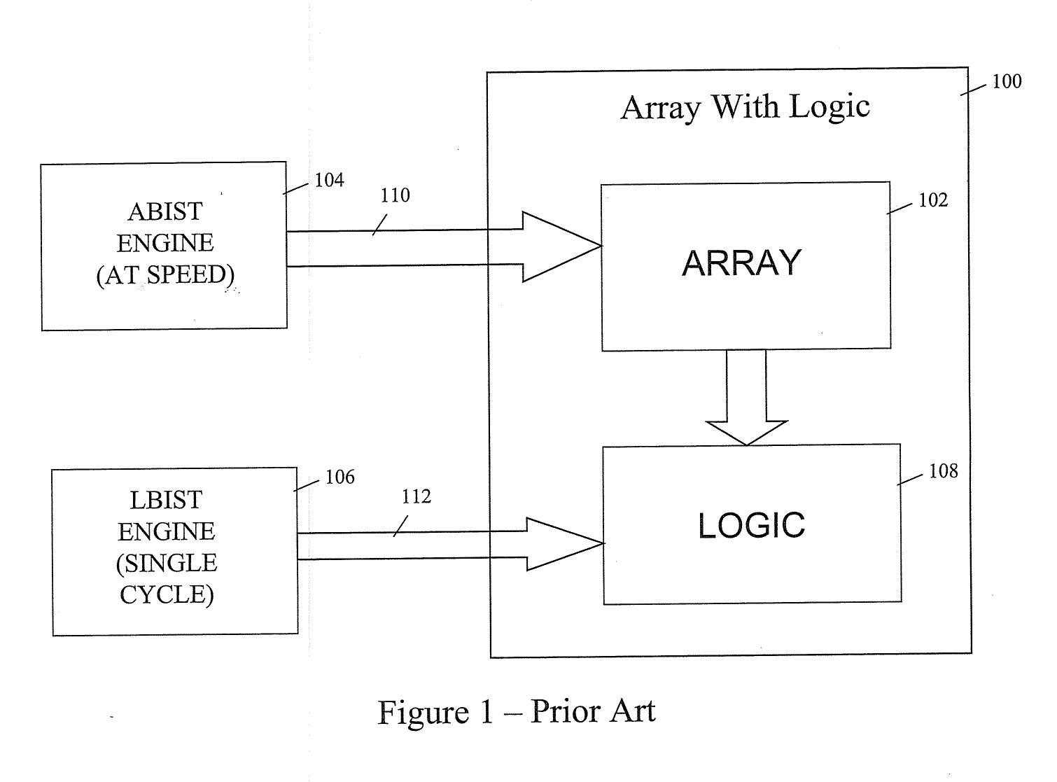

Referring initially to FIG. 1, there is shown a schematic block diagram of an existing ABIST/LBIST testing approach. As indicated above, a traditional method for testing a memory array with logic 100 in an integrated circuit device is to test the SRAM cells of the array portion 102 with an ABIST engine 104 running at speed, and to then use an LBIST engine 106 to test the remaining logic 108 (e.g., hit logic, multiplexers, etc.) downstream from the array 102, in a single cycle. Here, the ABIST test data 110 from the ABIST engine 104 is communicated to the array 102 only, whereas the LBIST test data 112 from the LBIST engine 106 is communicated to the logic 108 only.

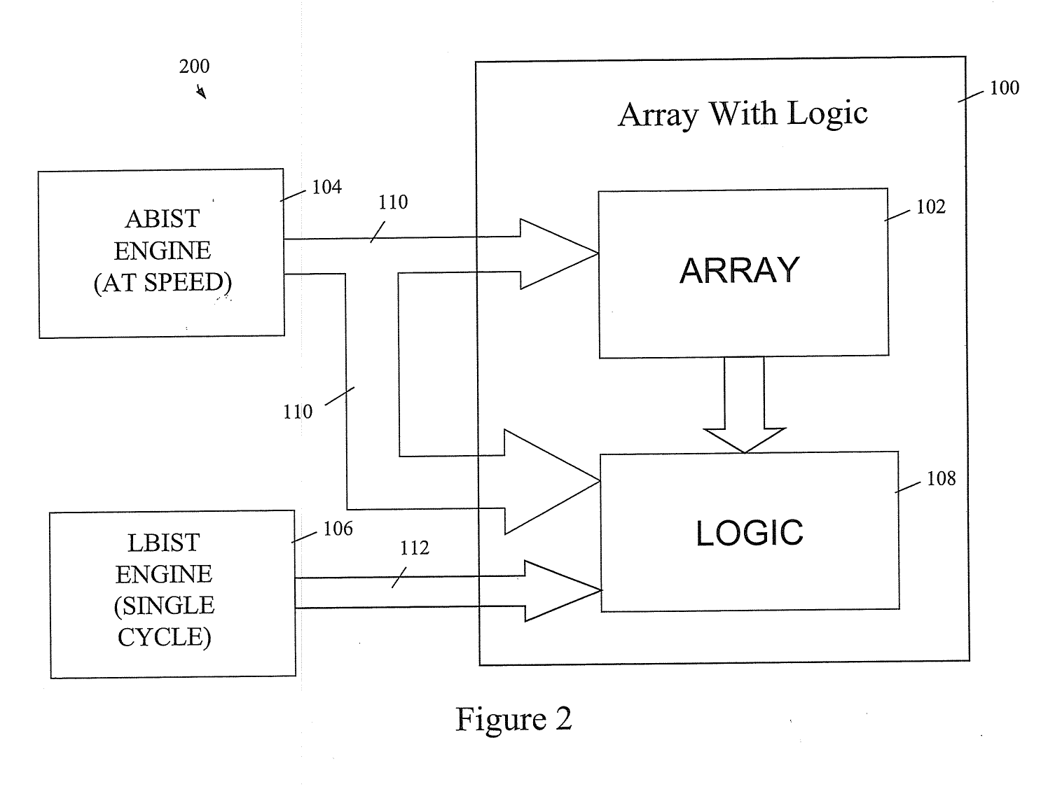

In contrast, FIG. 2 is a schematic block diagram of a simultaneous memory and logic testing scheme 200 using ABIST, in accordance with an embodiment of the invention. Although this approach still selectively allows for a traditional ABIST/LBIST testing methodology, there is now also the capability to simultaneously test both the SRAM and the logic portion of the macro, at speed, using a single pass/fail compare latch as described below. Conceptually, the ABIST test data 110 from the ABIST engine 104 is communicated both to the array 102, as well as to the logic 108. That is, the present embodiments provide for a wide variety of multi-cycle read and write patterns as opposed to the traditional single-cycle, write-through LBIST patterns.

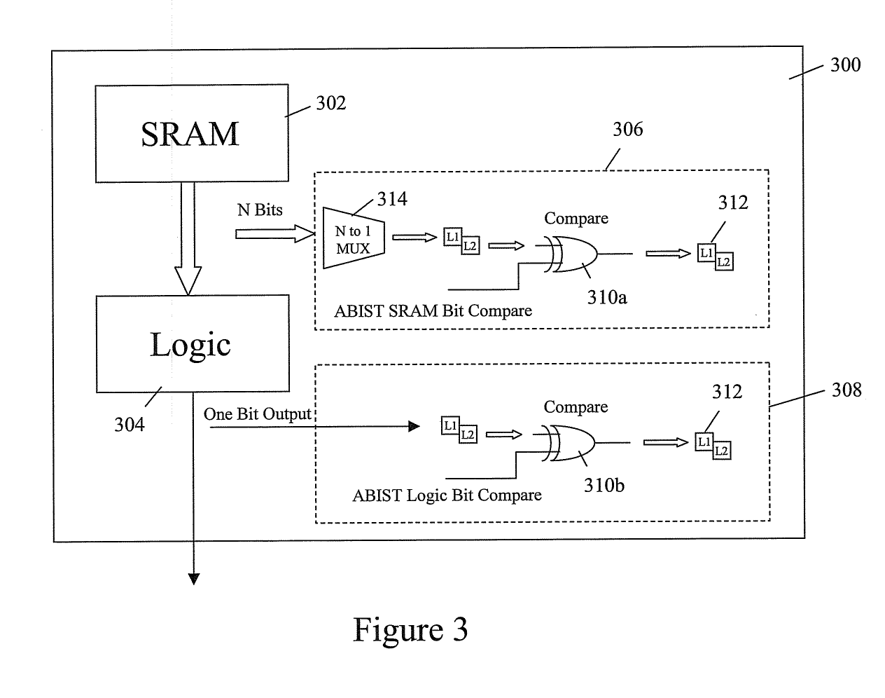

Referring now to FIG. 3, there is shown a schematic block diagram of an SRAM macro 300 configured for simultaneous memory and logic testing using ABIST, in accordance with a further embodiment of the invention. The macro 300 includes an SRAM array 302 and associated logic 304. In addition, the macro 300 includes a first ABIST pass/fail compare latch circuit 306 associated with the SRAM array 302 and a second ABIST pass/fail compare latch circuit 308 associated with the logic 304. Both the first and second ABIST pass/fail compare latch circuits 306, 308 employ a single-bit compare circuit 310a, 310b, respectively, (e.g., an exclusive OR (XOR) gate) that compares a latched output bit to a reference bit. The results of the compare operation for both the first and second ABIST pass/fail compare latch circuits 306, 308 are stored in a single pass/fail result latch 312.

In the case of the SRAM array 302, there are several (N) bits that are output therefrom. Thus, a specific output bit from the SRAM is selected via an N to 1 multiplexer 314. The selected bit is compared, using compare circuit 310a, with an ABIST SRAM bit compare signal (e.g., from the ABIST engine 104). In the case of the logic 304, the one bit output therefrom is compared, using compare circuit 310b, with an ABIST Logic bit compare signal (e.g., from the ABIST engine 104).

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of testing an integrated circuit device, the integrated circuit device having a memory array portion and a logic portion, the method comprising:
providing test data to the memory array portion of the integrated circuit device using Array Built-In Self Test (ABIST) circuitry; and
simultaneously testing the logic portion of the integrated circuit device using the ABIST circuitry, wherein both the memory array portion and the logic portion of the integrated circuit device are tested at speed.

2. The method of claim 1, further comprising capturing test results for both the memory array portion and the logic portion of the integrated circuit device in a single output latch.

3. The method of claim 2, further comprising individually testing each memory cell within the memory array portion with respect to an ABIST bit compare signal.

4. The method of claim 3, further comprising utilizing a multiplexer for individually testing each memory cell within the memory array portion, so as to enable isolation of a fail condition to one of the memory array portion and the logic portion.

5. A method of testing a static random access memory (SRAM) macro device having an SRAM array portion and a logic portion, the method comprising:
providing test data to the SRAM array portion of the SRAM macro device using Array Built-In Self Test (ABIST) circuitry; and
simultaneously testing the logic portion of the SRAM macro device using the ABIST circuitry, wherein both the SRAM array portion and the logic portion of the SRAM macro device are tested at speed.

6. The method of claim 5, further comprising capturing test results for both the SRAM array portion and the logic portion of the SRAM macro device in a single output latch.

7. The method of claim 6, further comprising individually testing each memory cell within the SRAM array portion with respect to an ABIST bit compare signal.

8. The method of claim 7, further comprising utilizing a multiplexer for individually testing each memory cell within the SRAM array portion, so as to enable isolation of a fail condition to one of the SRAM array portion and the logic portion.

9. An integrated circuit device, comprising:
a memory array portion and a logic portion;
an Array Built-In Self Test (ABIST) engine configured to provide ABIST data to the memory array portion; and
a Logic Built-In Self Test (LBIST) engine configured to provide LBIST data to the logic portion;
wherein the ABIST engine is further configured to selectively provide ABIST data to the logic portion so as to simultaneously test the memory array and logic portions of the integrated circuit device at speed.

10. The device of claim 9, further comprising a single output latch for capturing test results for both the memory array portion and the logic portion of the integrated circuit device.

11. The device of claim 10, further comprising a multiplexer for individually testing each memory cell within the memory array portion, so as to enable isolation of a fail condition to one of the memory array portion and the logic portion.

12. A static random access memory (SRAM) macro device, comprising:
an SRAM array portion and a logic portion;
an Array Built-In Self Test (ABIST) engine configured to provide ABIST data to the SRAM array portion; and
a Logic Built-In Self Test (LBIST) engine configured to provide LBIST data to the logic portion;
wherein the ABIST engine is further configured to selectively provide ABIST data to the logic portion so as to simultaneously test the SRAM array and logic portions of the SRAM macro device at speed.

13. The device of claim 12, further comprising a single output latch for capturing test results for both the SRAM array portion and the logic portion of the SRAM macro device.

14. The device of claim 13, further comprising a multiplexer for individually testing each memory cell within the SRAM array portion, so as to enable isolation of a fail condition to one of the SRAM array portion and logic portion.
